(19) United States
(12) Patent Application Publication
(10) Pub. No.: US 2008/0211494 A1
(43) Pub. Date: Sep. 4, 2008

(54) Device Comprising Magneto Resistive System

(75) Inventors: Hans Van Zon, Eindhoven (NL); Bart Michel De Boer, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/995,715

(22) PCT Filed: Jul. 14, 2006
(86) PCT No.: PCT/IB2006/052416

§ 371 Date: Jan. 15, 2008

(30) Foreign Application Priority Data
Jul. 21, 2005 (EP) 05106703.1

(51) Int. Cl. G01R 33/09

(52) U.S. Cl. 324/252

(57) ABSTRACT

Devices (1) comprising magneto resistive systems (2) for detecting incoming magnetic fields and comprising first/second branches with first/second magneto resistive elements (21-22) having first/second resistance values depending on the incoming magnetic fields according to first/second response curves are provided with shifting means for shifting the first/second response curves of the first/second branches into first/second directions to get an adapted linear behavior. The shifting means comprise first/second structures of the first/second branches resulting in a first/second local fields at the first/second branches such that the first/second response curves of the first/second branches are shifted into the first/second directions. The first/second branches comprise further first/second magneto resistive elements (26b,26c,27b,27c) coupled to the first/second magneto resistive elements (26a,27a) such that first/second currents flowing through these first/second magneto resistive elements (26a-26c,27a-27c) result in the first/second local fields at the first/second branches. The first/second structures comprise first/second meander structures (36,37) wherein first/second parts (36a-36c,37a-37c) comprise different first sizes such as alternating first/second widths.

The invention relates to a device comprising a magneto resistive system for detecting an incoming magnetic field, and also relates to a magneto resistive system, to shifting means, and to a method for detecting an incoming magnetic field via a magneto resistive system.

Examples of such a device are vehicles, crafts, planes and consumer products. Further examples of such a device are automotive products, rotational speed sensors, angular sensors and joysticks. Examples of such a magneto resistive system are systems comprising magneto resistive elements such as giant magneto resistance elements and anisotropic magneto resistance elements.

A prior art device is known from U.S. Pat. No. 6,580,587 B1, which discloses a magneto resistive system comprising giant magneto resistance elements. As disclosed in column 7 lines 48-66 of U.S. Pat. No. 6,580,587 B1, to use a bridge comprising four giant magneto resistance elements as a sensor, a variation in a resistance value of a first element and a fourth element should be different from a variation in a resistance value of a second element and a third element. This is accomplished through shielding one of the sets of elements or through biasing one set of elements to alter the transfer curves of this set of elements or through patterning one of the sets of elements differently from the other set of elements.

The known device is disadvantageous, inter alia, owing to the fact that its magneto resistive system has a given linearity that is not to be changed. FIGS. 4A and 4B of U.S. Pat. No. 6,580,587 B1 illustrate this.

It is an object of the invention, inter alia, to provide a device comprising a magneto resistive system with an adjustable linearity.

Further objects of the invention are, inter alia, to provide a magneto resistive system with an adjustable linearity, and to provide shifting means for use in a magneto resistive system with an adjustable linearity, and to provide a method for detecting an incoming magnetic field via a magneto resistive system with an adjustable linearity.

The device according to the invention comprises a magneto resistive system for detecting an incoming magnetic field, the magneto resistive system comprising a first branch and a second branch, the first branch comprising at least one first magneto resistive element having a first resistance value depending on the incoming magnetic field according to a first response curve, the second branch comprising at least one second magneto resistive element having a second resistance value depending on the incoming magnetic field according to a second response curve, the device further comprising shifting means for shifting a first response curve of the first branch into a first direction and for shifting a second response curve of the second branch into a second direction, the first direction and the second direction being different from each other.

By introducing the shifting means for shifting a first response curve of the first branch into a first direction and for shifting a second response curve of the second branch into a different second direction, the magneto resistive system will show a linearity or a non-linearity that depends on the shifts of the response curves. This is a great advantage and allows the linearity of the magneto resistive system to be increased (for example for measuring purposes) or to be decreased (for example for sound generation purposes).

The invention is further advantageous, inter alia, in that sensors based on this principle will show an adjustable behavior.

Such shifting means for example comprise a magnet per branch. Owing to the fact that magnets cannot be made unlimitedly small and that the magnetic field of a magnet will not just reach an intended branch but will also reach a non-intended branch, the shifting means in the form of magnets will result in the magneto resistive system needing to be relatively large. The following embodiments however allow the magneto resistive system to be relatively small.

An embodiment of the device according to the invention is defined by the shifting means comprising a first structure of the first branch and a second structure of the second branch, the first structure resulting in a first local field at the first branch and the second structure resulting in a second local field at the second branch. In other words, according to this embodiment the shifting means are realized through giving a branch a certain structure, whereby a bias current that flows via the structure will introduce the local field. In yet other words, the structures of the branches together with the bias currents flowing via these structures define the shifting means. The first structure results in a first local field at the first branch (for example at the first magneto resistive element) such that the first response curve of the first branch is shifted into the first direction and the second structure results in a second local field at the second branch (for example at the second magneto resistive element) such that the second response curve of the second branch is shifted into the second direction.

An embodiment of the device according to the invention is defined by the first branch comprising at least one further first magneto resistive element coupled to the first magneto resistive element such that a first current flowing through these first magneto resistive elements results in the first local field at the first branch, and the second branch comprising at least one further second magneto resistive element coupled to the second magneto resistive element such that a second current flowing through these second magneto resistive elements results in the second local field at the second branch. One way of giving each branch its own structure is using two or more magneto resistive elements coupled to each other per branch.

An embodiment of the device according to the invention is defined by the first magneto resistive elements comprising first magneto resistive stripes with first conducting layers coupled to the first magneto resistive stripes via first isolation layers, the first conducting layers conducting the first current between the coupled first magneto resistive elements (first current return path), and the second magneto resistive elements comprising second magneto resistive stripes with second conducting layers coupled to the second magneto resistive stripes via second isolation layers, the second conducting layers conducting the second current between the coupled second magneto resistive elements (second current return path). This way, per branch comprising two or more magneto resistive elements coupled to each other, the current exchanged via these two or more magneto resistive elements will enhance the local field.

An embodiment of the device according to the invention is defined by the first structure comprising a first meander structure wherein at least two first parts comprise different first sizes, and the second structure comprising a second meander structure wherein at least two second parts comprise different second sizes. An other way of giving each branch its own structure is using different meander structures for the different branches. A part for example corresponds with a magneto resistive stripe.

An embodiment of the device according to the invention is defined by the first parts comprising alternating first widths, and the second parts comprising alternating second widths. This way, no area is lost for coupling two or more magneto resistive elements per branch and no additional lithography steps are required. A part for example corresponds with a magneto resistive stripe.

An embodiment of the device according to the invention is defined by the shifting means comprising a first generator for generating a first signal at the first branch resulting in a first current and comprising a second generator for generating a second signal at the second branch resulting in a second current, the first current resulting in a first local field at the first branch and the second current resulting in a second local field at the second branch. In other words, according to this embodiment, the shifting means are realized through introducing the first and second generators, the first and second signals being different from magneto resistive element bias signals. In yet other words, the first and second generators define the shifting means separately from the biasing of the magneto resistive elements. The first and second generators may, each or together, comprise one or more current sources for generating a current or one or more voltage sources for generating a voltage, which voltage is to be converted into a current. The current may flow via an element or a conductor located close to the branch.

An embodiment of the device according to the invention is defined by the magneto resistive system further comprising a third branch and a fourth branch, the third branch comprising at least one third magneto resistive element having a third resistance value depending on an incoming magnetic field according to a third response curve, the fourth branch comprising at least one fourth magneto resistive element having a fourth resistance value depending on the incoming magnetic field according to a fourth response curve, the device further comprising further shifting means for shifting a third response curve of the third branch into the second direction and for shifting a fourth response curve of the fourth branch into the first direction. Such a magneto resistive system comprising four branches forms a Wheatstone bridge. The respective third and fourth branches may be in correspondence with the respective second and first branches.

An embodiment of the device according to the invention is defined by the magneto resistive elements comprising giant magneto resistance elements or comprising anisotropic magneto resistance elements with barberpoles. Further kinds of elements are not to be excluded.

Embodiments of the magneto resistive system according to the invention and of the shifting means according to the invention and of the method according to the invention correspond with the embodiments of the device according to the invention.

The invention is based upon an insight, inter alia, that a linearity or a non-linearity of a magneto resistive system is defined by the response curves of the magneto resistive elements, and is based upon a basic idea, inter alia, that a first response curve of a first branch is to be shifted into a first direction and a second response curve of a second branch is to be shifted into a different second direction for adapting a linearity of the magneto resistive system.

The invention solves the problem, inter alia, to provide a device comprising a magneto resistive system with an adjustable linearity or with an adjustable non-linearity, and is advantageous, inter alia, in that sensors based on this principle will show an adjustable behavior.

These and other aspects of the invention will be apparent from and elucidated with reference to the embodiments(s) described hereinafter.

In the drawings:

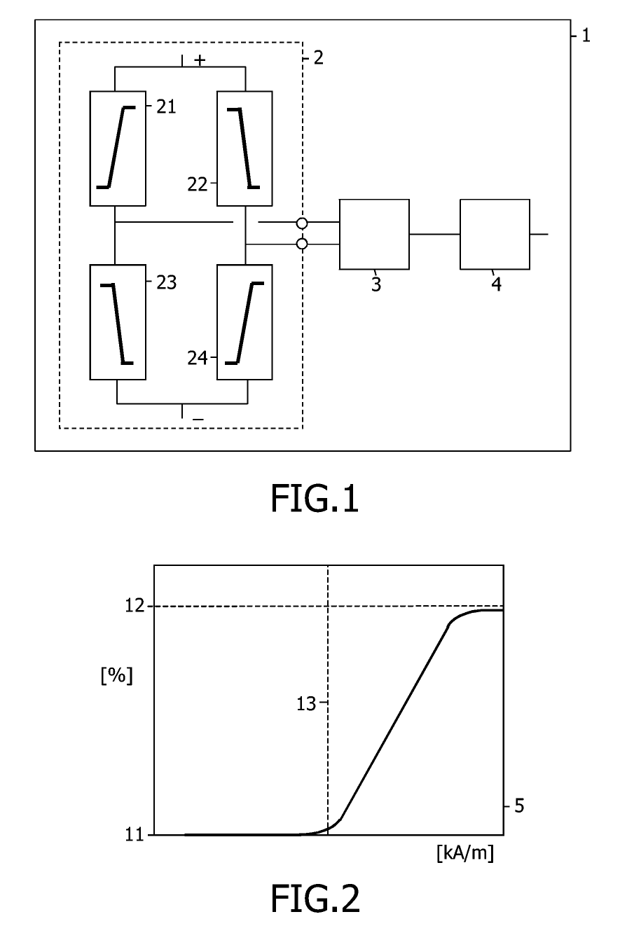

FIG. 1 shows diagrammatically a device according to the invention comprising a magneto resistive system according to the invention,

FIG. 2 shows a prior art response curve of a prior art magneto resistive element,

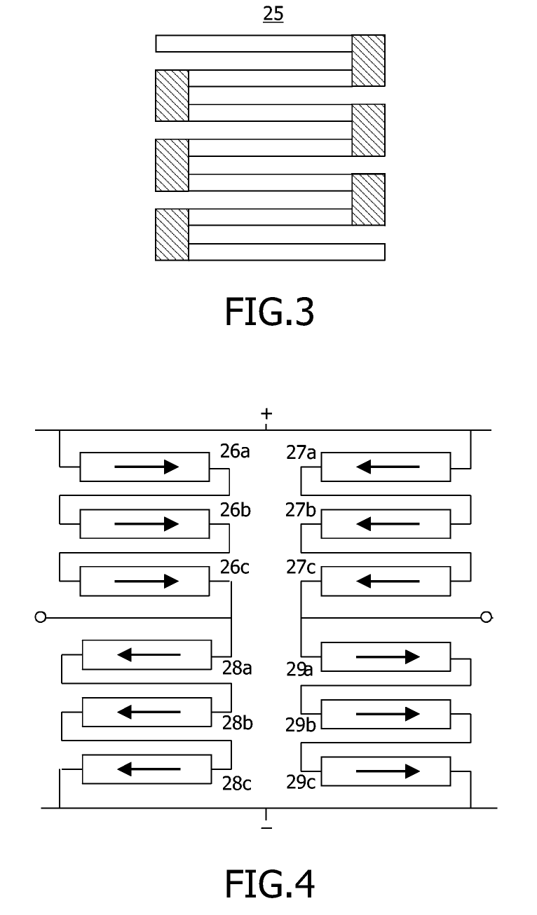

FIG. 3 shows a prior art branch having a prior art meander structure of a prior art magneto resistive system,

FIG. 4 shows a magneto resistive system according to the invention in the form of a Wheatstone bridge comprising four branches each with three serial magneto resistive elements,

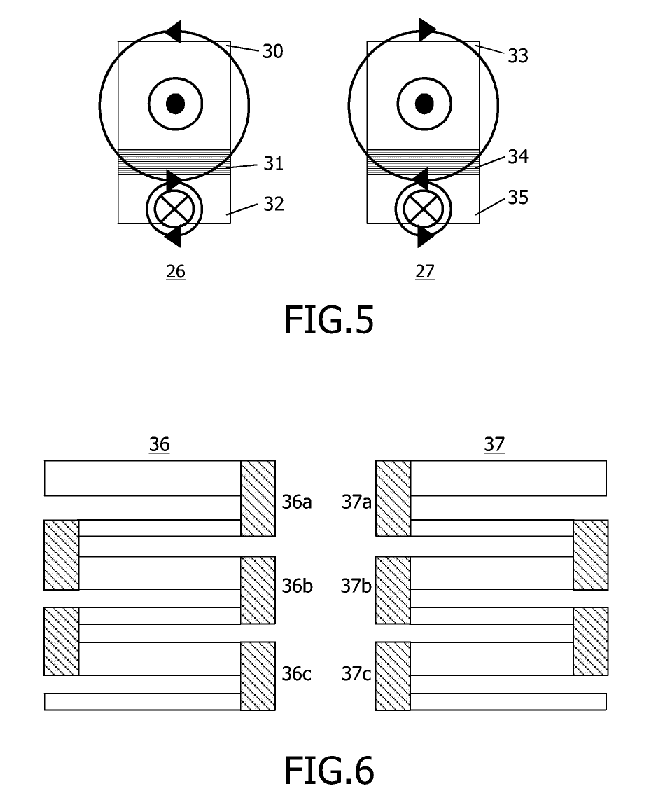

FIG. 5 shows two branches each comprising a magneto resistive stripe with a conducting layer coupled to the magneto resistive stripe via an isolation layer,

FIG. 6 shows two branches each having a meander structure according to the invention,

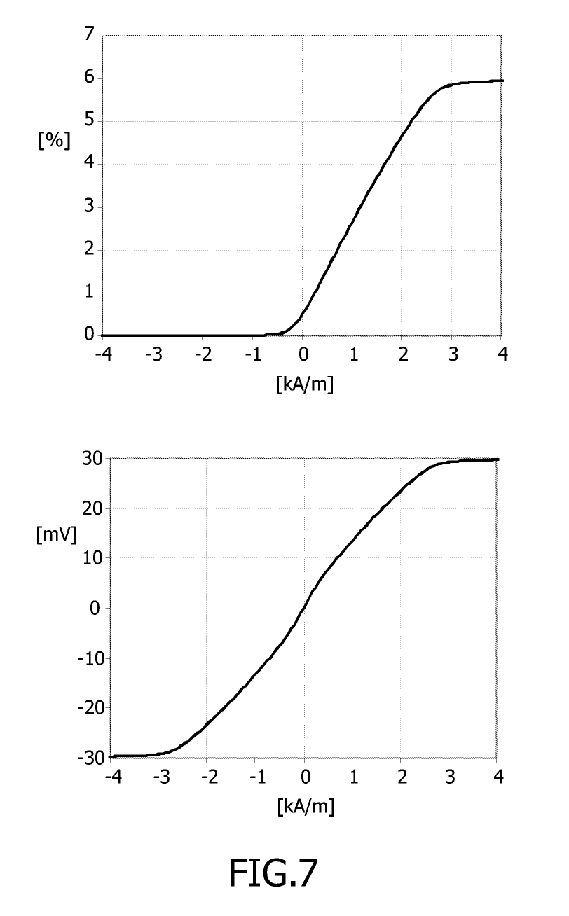

FIG. 7 shows a response curve of a magneto resistive element and a magneto resistive system according to the invention in the form of a Wheatstone bridge,

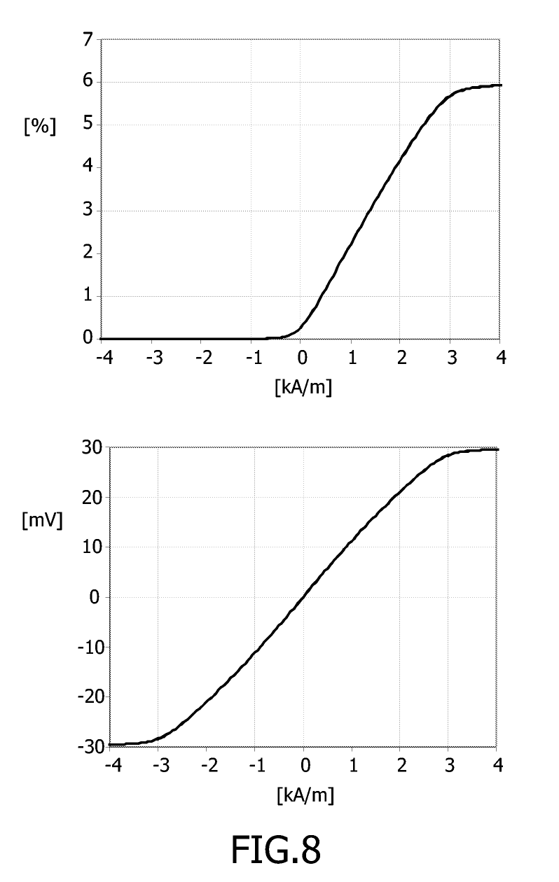

FIG. 8 shows a response curve of a magneto resistive element and a magneto resistive system according to the invention in the form of a Wheatstone bridge, and

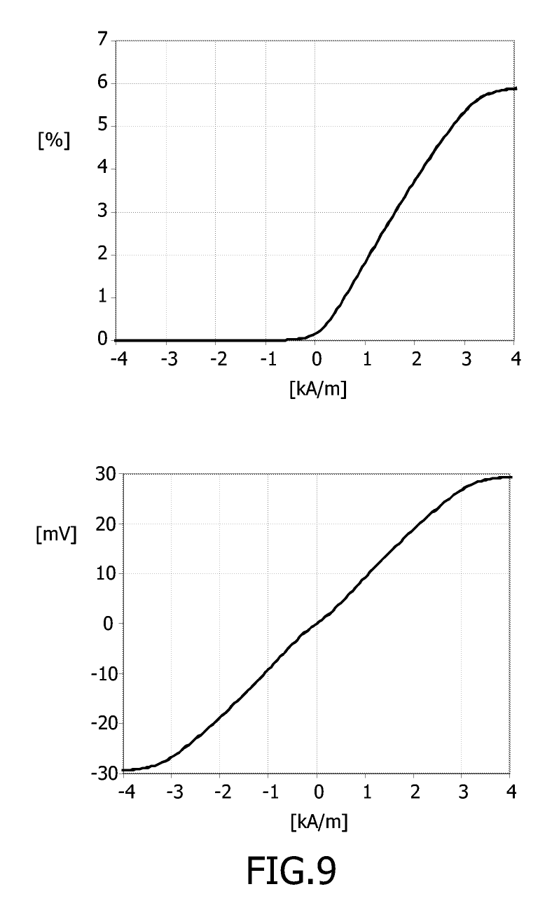

FIG. 9 shows a response curve of a magneto resistive element and a magneto resistive system according to the invention in the form of a Wheatstone bridge.

The device 1 according to the invention shown in FIG. 1 comprises a magneto resistive system 2 according to the invention. The magneto resistive system 2 according to the invention comprises for example four branches for example in the form of a Wheatstone bridge. Each branch comprises a magneto resistive element 21-24. Outputs of the Wheatstone bridge are coupled via a converter 3 to a processor 4. The response curves of the first and fourth magneto resistive elements 21 and 24 are the approximately opposite (mirrored via a vertical line at zero incoming magnetic field) of the response curves of the second and third magneto resistive elements 22 and 23.

In FIG. 2 a prior art response curve of a prior art magneto resistive element is shown for limited incoming magnetic fields (% versus kA/m). For negative incoming magnetic fields, a resistance value of the prior art magneto resistive element does not change (horizontal line 11). Shortly before the incoming magnetic field gets a value zero and at the incoming magnetic field being zero (vertical line 13), the resistance value of the prior art magneto resistive element starts to change a little (0 to +0.5%). For positive incoming magnetic fields, the resistance value of the prior art magneto resistive element increases (+0.5% to +6%), until a maximum has been reached (horizontal line 12).

In FIG. 3 a prior art branch 25 having a prior art meander structure of a prior art magneto resistive system is shown. For this prior art meander structure comprising a series of stripes, a response curve of a branch is substantially identical to a response curve of a stripe.

In FIG. 4 a magneto resistive system according to the invention is shown in the form of a Wheatstone bridge comprising four branches 26-29 each with three serial magneto resistive elements 26a-26c,27a-27c,28a-28c,29a-29c. Here, per branch, a current flows through each magneto resistive element in the same direction (for the first and fourth branches 26 and 29 from left to right and for the second and third branches 27 and 28 from right to left). This is realized by placing a current return path between the elements (stripes). In FIG. 3, a shifting of a response curve of a branch is substantially averaged out owing to the fact that there is a back and forth running current. In FIG. 4, this averaging effect is eliminated, because, per branch, the current flows through each magneto resistive element in the same direction. As a result, a first response curve of the first branch 26 is shifted into a first direction and a second response curve of the second branch 27 is shifted into a second direction, and a third response curve of the third branch 28 is shifted into the second direction and a fourth response curve of the fourth branch 29 is shifted into the first direction. The first structure of the first branch 26 results in a first local field being present at the first branch 26 for shifting the first response curve of the first branch 26 into the first direction. The second structure of the second branch 27 results in a second local field being present at the second branch 27 for shifting the second response curve of the second branch 27 into the second direction. The third structure of the third branch 28 results in a third local field being present at the third branch 28 for shifting the third response curve of the third branch 28 into the second direction. The fourth structure of the fourth branch 29 results in a fourth local field being present at the fourth branch 29 for shifting the fourth response curve of the fourth branch 29 into the first direction. More precisely, the first (second, third, fourth) local field comprises, in this case, three local sub-fields, one sub-field at each element.

The invention is based upon an insight, inter alia, that in order to get a more linear magneto resistive system, for example for measuring purposes, a slope of the response curve of the magneto resistive element at zero incoming magnetic field should be about half (25% to 75%, preferably 40% to 60%, further preferably 50%) of the maximum slope. This is to be reached through shifting the respective response curves in the respective first and second directions, one of these directions for example being a left direction and the other one then being a right direction. Of course, somewhere there will be an optimum, and when shifting the response curves beyond this optimum, the linearity will decrease. By shifting the response curves in opposite directions, a less linear or more non-linear magneto resistive system is realized, for example for sound generation purposes. So, generally, by shifting the response curves in different directions, the magneto resistive system gets an adapted linearity.

In FIG. 5 the two branches 26 and 27 are shown each comprising a magneto resistive stripe 32 and 35 with a conducting layer 30 and 33 coupled to the magneto resistive stripe 32 and 35 via an isolation layer 31 and 34. So, in this embodiment, the current return path is located on top of the magneto resistive stripes 32 and 35 via the conducting layers 30 and 33 and as a result the local fields at the first and second branches 26 and 27 are enhanced.

In FIG. 6 two branches each having a meander structure according to the invention are shown. A first structure comprises a first meander structure 36 wherein three first parts 36a,36b,36c comprise different first sizes, and a second structure comprises a second meander structure 37 wherein three second parts 37a,37b,37c comprise different second sizes. Each first part 36a,36b,36c comprises for example two serial stripes with alternating first widths, and each second part 37a,37b,37c comprises for example two serial stripes with alternating second widths. This results in alternating current densities and alternating local fields.

So, according to the invention, shifting means for shifting the first response curve of the first branch into the first direction and for shifting the second response curve of the second branch into the second direction have been introduced. In the Figures, these shifting means have been realized through selecting different structures, through which structures the biasing currents of the magneto resistive system flow. Alternatively, the shifting means may be realized through a first generator for generating a first signal at the first branch resulting in a first current and through a second generator for generating a second signal at the second branch resulting in a second current, the first current resulting in a first local field at the first branch and the second current resulting in a second local field at the second branch. Both first and second generators may be part of one and the same generator or may be different generators. The shifting means may further comprise a third generator for generating a third signal at the third branch resulting in a third current and through a fourth generator for generating a fourth signal at the fourth branch resulting in a fourth current, the third current resulting in a third local field at the third branch and the fourth current resulting in a fourth local field at the fourth branch. Both third and fourth generators may be part of one and the same generator or may be different generators. These first and second (and third and fourth) signals are different from the biasing currents of the magneto resistive elements and require separate conductors/elements.

In FIGS. 7, 8 and 9, response curves of a magneto resistive element and a magneto resistive system according to the invention in the form of a Wheatstone bridge are shown for limited incoming magnetic fields (% versus kA/m in the upper graphs and mV versus kA/m in the lower graphs). Clearly, a linear behavior has been reached in FIG. 8.

In a minimum situation the magneto resistive system 2 according to the invention will comprise two branches. Preferably, in an extended situation, it will comprise four branches. The magneto resistive elements 21-24 may comprise giant magneto resistance elements or anisotropic magneto resistance elements with barberpoles, without excluding further kinds of magneto resistive elements.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “to comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

1. Device (1) comprising a magneto resistive system (2) for detecting an incoming magnetic field, the magneto resistive system (2) comprising a first branch and a second branch, the first branch comprising at least one first magneto resistive element (21) having a first resistance value depending on the incoming magnetic field according to a first response curve, the second branch comprising at least one second magneto resistive element (22) having a second resistance value depending on the incoming magnetic field according to a second response curve, the device (1) further comprising shifting means for shifting a first response curve of the first branch into a first direction and for shifting a second response curve of the second branch into a second direction, the first direction and the second direction being different from each other.

2. Device (1) according to claim 1, the shifting means comprising a first structure of the first branch and a second structure of the second branch, the first structure resulting in a first local field at the first branch and the second structure resulting in a second local field at the second branch.

3. Device (1) according to claim 2, the first branch comprising at least one further first magneto resistive element (26b,26c) coupled to the first magneto resistive element (26a) such that a first current flowing through these first magneto resistive elements (26a-26c) results in the first local field at the first branch, and the second branch comprising at least one further second magneto resistive element (27b,27c) coupled to the second magneto resistive element (27a) such that a second current flowing through these second magneto resistive elements (27a-27c) results in the second local field at the second branch.

4. Device (1) according to claim 3, the first magneto resistive elements (26a-26c) comprising first magneto resistive stripes (32) with first conducting layers (30) coupled to the first magneto resistive stripes (32) via first isolation layers (31), the first conducting layers (30) conducting the first current between the coupled first magneto resistive elements (26a-26c), and the second magneto resistive elements (27a-27c) comprising second magneto resistive stripes (35) with second conducting layers (33) coupled to the second magneto resistive stripes (35) via second isolation layers (34), the second conducting layers (33) conducting the second current between the coupled second magneto resistive elements (27a-27c).

5. Device (1) according to claim 2, the first structure comprising a first meander structure (36) wherein at least two first parts (36a,36b,36c) comprise different first sizes, and the second structure comprising a second meander structure (37) wherein at least two second parts (37a,37b,37c) comprise different second sizes.

6. Device (1) according to claim 5, the first parts (36a,36b,36c) comprising alternating first widths, and the second parts (37a,37b,37c) comprising alternating second widths.

7. Device (1) according to claim 1, the shifting means comprising a first generator for generating a first signal at the first branch resulting in a first current and comprising a second generator for generating a second signal at the second branch resulting in a second current, the first current resulting in a first local field at the first branch and the second current resulting in a second local field at the second branch.

8. Device (1) according to claim 1, the magneto resistive system (2) further comprising a third branch and a fourth branch, the third branch comprising at least one third magneto resistive element (23) having a third resistance value depending on an incoming magnetic field according to a third response curve, the fourth branch comprising at least one fourth magneto resistive element (24) having a fourth resistance value depending on the incoming magnetic field according to a fourth response curve, the device (1) further comprising further shifting means for shifting a third response curve of the third branch into the second direction and for shifting a fourth response curve of the fourth branch into the first direction.

9. Device (1) according to claim 1, the magneto resistive elements (21-24) comprising giant magneto resistance elements or comprising anisotropic magneto resistance elements with barberpoles.

10. Magneto resistive system (2) as defined in claim 1.

11. Shifting means as defined in claim 1.

12. Method for detecting an incoming magnetic field via a magneto resistive system (2) comprising a first branch and a second branch, the first branch comprising at least one first magneto resistive element (21) having a first resistance value depending on an incoming magnetic field according to a first response curve, the second branch comprising at least one second magneto resistive element (22) having a second resistance value depending on the incoming magnetic field according to a second response curve, the method comprising the steps of shifting a first response curve of the first branch into a first direction and for shifting a second response curve of the second branch into a second direction, the first direction and the second direction being different from each other.
